(19) United States
(12) Patent Application Publication
(10) Pub. No.: US 2022/0416136 A1
(43) Pub. Date: Dec. 29, 2022

(54) Die bonding method of LED chip and display device

(71) Applicant: CHONGQING KONKA PHOTOELECTRIC TECHNOLOGY RESEARCH INSTITUTE CO., LTD., Chongaing (CN)

(72) Inventors: Jinxin AN, Chongqing (CN); Chung-yu CHOU, Chongqing (CN); Liu-chung LEE, Chongqing (CN); Tzu-ping LIN, Chongqing (CN); Kai-lun WANG, Chongqing (CN)

(21) Appl. No.: 17/295,884

(22) PCT Filed: Aug. 28, 2020
(86) PCT No.: PCT/CN2020/112180

§ 371 Date: May 21, 2021

(30) Foreign Application Priority Data
Mar. 16, 2020 (CN) 202010181202.6

(51) Int. Cl. H01L 33/62; H01L 33/00; H01L 25/075

(52) U.S. Cl. CPC H01L 33/62; H01L 33/0093; H01L 25/0753; H01L 2933/0066

(57) ABSTRACT

The application discloses a die bonding method of an LED chip and a display device. The method may include: a welding material is fixed on a metal pad of the LED chip, the LED chip fixed with the welding material is transferred onto a transient substrate, the metal pad of the LED chip on the transient substrate is aligned with a bonding pad on a receiving substrate, the welding material fixed on the LED chip is heated, and then the LED chip is fixed on the receiving substrate.

### TECHNICAL FIELD

The application relates to the technical field of Light Emitting Diode (LED) display, and in particular relates to a die bonding method of an LED chip and a display device.

### BACKGROUND

LED die bonding is called die bond or die packaging as well, and is a procedure of bonding a die to a designated area of a support through a colloid (which is conductive adhesive, insulating adhesive or a solder generally), in this way a heat path or a power path is formed and a condition for subsequent wiring and connection is provided.

A related die bonding method of an LED chip is shown in FIG. 1. A welding material 12 is printed on a bonding pad 11 of a substrate 10. Then a metal pad 131 of the LED chip 13 is aligned with the bonding pad 11 of the substrate 10, in this way the LED chip 13 is arranged on the substrate 10. The LED chip 13 is fixed on the substrate 10 in a mode of reflow soldering. The related die bonding method of the LED chip 13 is to print the welding material 12 onto the bonding pad 11 of the substrate 10 at a time, then arrange the LED chip 13 on the substrate 10 for the die bonding. In a process of arranging the LED chip to the substrate 10, the welding material 12 may be dried easily, in this way the reflow soldering and a die bonding process of the LED chip may be influenced.

Therefore, the related art remains to be further improved.

### SUMMARY

In consideration of disadvantages in the abovementioned related art, the application is intended to provide a die bonding method of an LED chip and a display device, to overcome problems that a welding material in a related die bonding method of the LED chip is printed onto a substrate at a time, the welding material may be dried easily during a process of arranging the LED chip to the substrate, and accordingly reflow soldering and a die bonding process of the LED chip may be influenced.

A first embodiment disclosed by the application is a die bonding method of an LED chip, wherein the method may include the following operations.

A welding material is fixed on a metal pad of the LED chip.

The LED chip fixed with the welding material is transferred onto a transient substrate.

A metal pad of the LED chip on the transient substrate is aligned with a bonding pad on a receiving substrate, the welding material fixed on the LED chip is heated, and then the LED chip is fixed on the receiving substrate.

In the die bonding method of the LED chip, the operation that the welding material is fixed on the metal pad of the LED chip may include the following operations.

The welding material is printed on the metal pad of the LED chip, to obtain an LED chip printed with the welding material.

The LED chip printed with the welding material is subjected to reflow soldering, in this way the welding material is fixed on the metal pad of the LED chip.

After the operation that the welding material is fixed on the metal pad of the LED chip, the die bonding method of the LED chip may further include the following operations.

The LED chip is subjected to spot inspection, sorting and examination, and the LED chip having a wavelength difference within a range defined based on one or more preset thresholds is transferred onto one blue film.

In the die bonding method of the LED chip, the operation that the LED chip fixed with the welding material is transferred onto the transient substrate may include the following operations.

Release glue is coated or cladded on the transient substrate.

The metal pad of the LED chip on the blue film is oriented toward a direction away from the transient substrate, and the LED chip fixed with the welding material is transferred onto the transient substrate through the release glue.

After the operations that the metal pad of the LED chip on the transient substrate is aligned with the bonding pad on the receiving substrate, the welding material fixed on the LED chip is heated, and the LED chip is fixed on the receiving substrate, the die bonding method of the LED chip may further include the following operation.

The transient substrate is removed.

In the die bonding method of the LED chip, the transient substrate may include a first transient substrate and a second transient substrate.

The operation that the LED chip fixed with the welding material is transferred onto the transient substrate may include the following operations.

First release glue is coated or cladded on the first transient substrate, and second release glue is coated or cladded on the second transient substrate.

A surface of the LED chip fixed with the welding material and having the metal pad is oriented toward the first transient substrate, and the LED chip fixed with the welding material is fixed on the first transient substrate through the first release glue.

A growth substrate is removed through a laser lift-off technology, a surface of the LED chip fixed with the welding material and opposite to the first transient substrate is oriented toward the second transient substrate, and the LED chip fixed with the welding material is fixed on the second transient substrate through the second release glue.

In the die bonding method of the LED chip, release conditions of the first release glue are different from release conditions of the second release glue.

After the operation that the LED chip fixed with the welding material is fixed on the second transient substrate through the second release glue, the method may further include the following operation.

The first transient substrate is removed.

After the operation that the first transient substrate is removed, the die bonding method of the LED chip may further include the following operations.

The metal pad of the LED chip fixed on the second transient substrate is aligned with the bonding pad on the receiving substrate, the welding material fixed on the LED chip is heated, and the LED chip is fixed on the receiving substrate, wherein a mode of heating the welding material fixed on the LED chip may include one of reflow soldering, vacuum baking or laser heating.

After the operations that the metal pad of the LED chip fixed on the second transient substrate is aligned with the bonding pad on the receiving substrate, the welding material fixed on the LED chip is heated, and the LED chip is fixed on the receiving substrate, the die bonding method of the LED chip may further include the following operation.

The second transient substrate is removed.

A second embodiment disclosed by the application is a display device, wherein the display device may include a display substrate fixed with an LED chip, and the LED chip is fixed on the display substrate with the die bonding method of the LED chip described in any of the above.

The application provides the die bonding method of the LED chip and the display device. The welding material is printed and fixed on the metal pad of the LED chip first, then the metal pad of the LED chip is aligned with the bonding pad on the receiving substrate, and the welding material on the LED chip is heated, in this way the LED chip is fixed on the receiving substrate. The whole die bonding process may not be limited by placement time after the welding material is printed, a manufacturing process is stable, and the method is suitable for manufacturing of an integrated large-size LED display device.

### BRIEF DESCRIPTION OF THE DRAWINGS

FIG. 1 is a process diagram of a related die bonding method of an LED chip.

FIG. 2 is a flow diagram of a preferred embodiment of a die bonding method of an LED chip provided by the application.

FIG. 3 is a process diagram of a die bonding method of an LED chip provided by an embodiment 1 of the application.

FIG. 4 is a process diagram of a die bonding method of an LED chip provided by an embodiment 2 of the application.

### DETAILED DESCRIPTION OF THE EMBODIMENTS

For making the purpose, technical solutions and advantages of the application clearer and more explicit, the application will further be described below in combination with drawings and embodiments in detail. It should be understood that the specific embodiments described here are adopted not to limit the application but only to explain the application.

A related die bonding method of an LED chip is to print a welding material on a substrate at a time, then arrange the LED chip on the substrate, to fix the LED chip on the substrate through reflow soldering, in this way the welding material may be dried easily during a process of arranging the LED chip to the substrate, and accordingly the reflow soldering and a die bonding process of the LED chip may be influenced. In order to solve the abovementioned problems, the application provides a die bonding method of an LED chip.

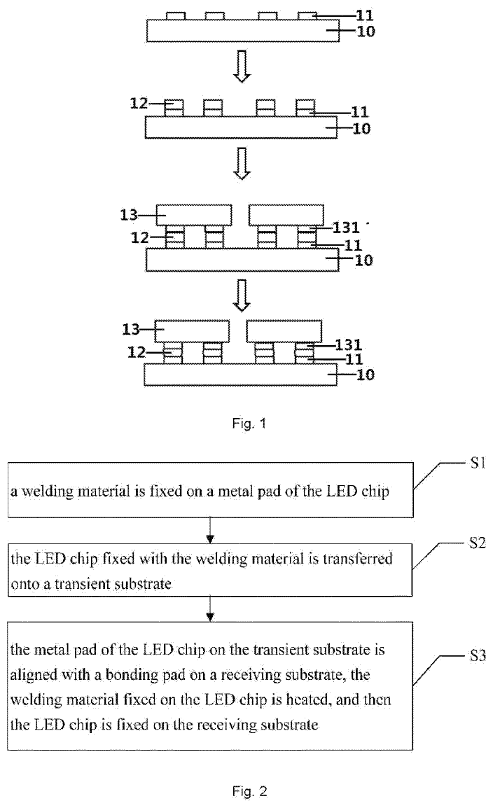

Please refer to FIG. 1, the die bonding method of the LED chip provided by the application may include the following operations.

S1, a welding material is fixed on a metal pad of the LED chip.

S2, the LED chip fixed with the welding material is transferred onto a transient substrate.

S3, the metal pad of the LED chip on the transient substrate is aligned with a bonding pad on a receiving substrate, the welding material fixed on the LED chip is heated, and then the LED chip is fixed on the receiving substrate.

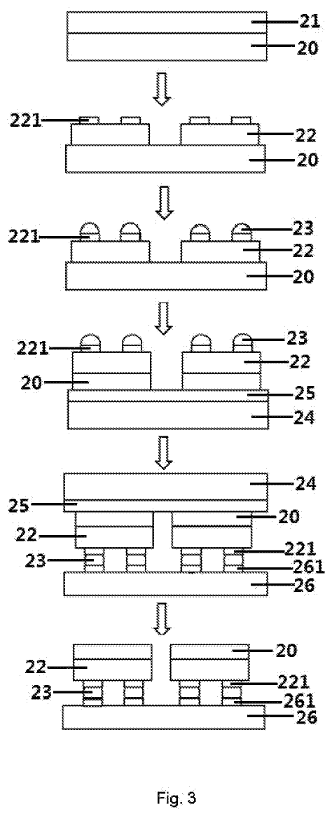

In a specific embodiment, because the related die bonding method of the LED chip is to print the welding material onto the substrate at a time, the welding material may be dried easily during a process of arranging the LED chip to the substrate, and accordingly the die bonding process and the reflow soldering of the LED chip may be influenced. In order to solve the abovementioned problems, an embodiment 1 of the application provides a die bonding method of an LED chip, and a process diagram is shown in FIG. 3. In the embodiment, when the LED chip 22 is prepared on an epitaxial layer 21 in the embodiment, the welding material 23 is fixed on the metal pad 221 of the LED chip 22, to obtain the LED chip 22 fixed with the welding material 23. Then the LED chip 22 fixed with the welding material 23 is transferred onto the transient substrate 24. The metal pad 221 on the LED chip 22 on the transient substrate 24 is aligned with the bonding pad 261 on the receiving substrate 26 finally. The welding material 23 fixed on the LED chip 22 is heated to melt down the welding material 23, and accordingly the LED chip 22 is fixed on the receiving substrate 26, wherein a mode of heating may include, but not be limited to, reflow soldering, vacuum baking, laser heating and so on. When the LED chip 22 is subjected to die bonding in the embodiment, the welding material 23 is fixed on the metal pad 221 of the LED chip 22 first, then the metal pad 221 of the LED chip 22 is aligned with the bonding pad 261 of the receiving substrate 26, to directly melt down the welding material 23 on the metal pad 221 of the LED chip 22, and accordingly fix the LED chip 22 on the receiving substrate 26. Because the welding material is fixed on the metal pad 221 of the LED chip 22, the whole die bonding process may not be limited by placement time when the welding material 23 is printed, and a manufacturing process is stable.

In a specific embodiment, before the operation S1, the method may further include the following operations.

S01, a growth substrate is provided.

S02, the epitaxial layer is formed on the growth substrate.

During specific implementation, as shown in FIG. 3, in the embodiment the growth substrate 20 is provided first. The growth substrate 20 may include, but not be limited to, a sapphire, silicon carbide or silicon. Then the epitaxial layer 21 is formed on the growth substrate 20 with a mode of MOCVD and so on. Multiple procedures, including etching, electrode growth, thinning and cutting are implemented on the epitaxial layer 21 finally, to prepare the LED chip 22 including the metal pad 221.

In a specific embodiment, the operation S1 may include the following operations.

S11, the welding material is printed on the metal pad of the LED chip, to obtain the LED chip printed with the welding material.

S12, the LED chip printed with the welding material is subjected to reflow soldering, in this way the welding material is fixed on the LED chip.

During the specific implementation, when the LED chip 22 is prepared on the epitaxial layer 21, solder paste and other welding materials 23 are printed on the metal pad 221 of the LED chip 22, to obtain the LED chip 22 printed with the welding material 23. Then the LED chip 22 printed with the welding material 23 is subjected to the reflow soldering, in this way the welding material 23 is fixed on the LED chip 22. A mode of printing the welding material 23 may include, but not be limited to, printing in which a steel mesh serves as a mask, spot printing and so on.

In a specific embodiment, after the operation S1, the method may further include the following operations.

M1, the LED chip is subjected to spot inspection, sorting and examination, and the LED chip having a wavelength difference within a range defined based on one or more preset thresholds is transferred onto one blue film.

During the specific implementation, the LED chip 22 obtained in the preceding operations and fixed with the welding material 23 is loaded on the growth substrate 20. When the welding material 23 is fixed on the LED chip 22 in the embodiment, the growth substrate 20 is further cut, and multiple LED chips 22 connected through the growth substrate 20 are cut into multiple independent LED chips 22. In order to further ensure a yield of the LED chip, after the multiple independent LED chips 22 are obtained in the embodiment and the multiple independent LED chips 22 are subjected to spot inspection, sorting, examination and other procedures, the LED chips 22 having the wavelength difference within the range defined based on one or more preset threshold are transferred onto one blue film.

In a specific embodiment, the operation S2 may include the following operations.

S21, release glue is coated or cladded on the transient substrate.

S22, the metal pad of the LED chip on the blue film is oriented toward a direction away from the transient substrate, and the LED chip fixed with the welding material is transferred onto the transient substrate through the release glue.

During the specific implementation, after the LED chips 22 having the wavelength difference within the range of preset threshold are transferred onto one blue film, the transient substrate 24 coated or cladded with the release glue 25 is provided, and the LED chips 22 on the blue film are further transferred onto the transient substrate 24. During the specific transferring, the metal pad 221 of the LED chip 22 is oriented toward the direction away from the transient substrate 24, that is, the growth substrate 20 connecting with the LED chip 22 is in contact with the transient substrate 24, and the LED chip 22 is fixed on the transient substrate 24 through the growth substrate 20 in presence of the release glue 25. In a specific embodiment, the transient substrate 24 may include, but not be limited to, a glass plate, quartz glass, the sapphire or a silicon wafer, and the release glue 25 may include, but not be limited to, UV photolytic glue, pyrolytic glue and low-temperature dissolving glue.

In a specific embodiment, after the operation S3, the method may further include the following operation.

S4, the transient substrate is removed.

During the specific implementation, when the LED chip 22 is fixed on the transient substrate 24 through the growth substrate 20 in presence of the release glue 25, the metal pad 221 of the LED chip on the transient substrate 24 is aligned with the bonding pad 261 on the receiving substrate 26, and the welding material 23 fixed on the LED chip 22 is heated, in this way the welding material 23 is melted down, and the LED chip 22 is fixed onto the receiving substrate 26, wherein the mode of heating may include, but not be limited to, the reflow soldering, the vacuum baking and the laser heating. Because the transient substrate 24 and the LED chip 22 are fixed through the release glue 25, after the LED chip 22 is fixed onto the receiving substrate 26, the transient substrate 24 may be removed when release conditions of the release glue 25 are satisfied. For example, when the release glue 25 is the UV photolytic glue, after the LED chip 22 is fixed onto the receiving substrate 26, the transient substrate 24 may be removed by irradiating the transient substrate 24 with UV lights, and operations above are simple.

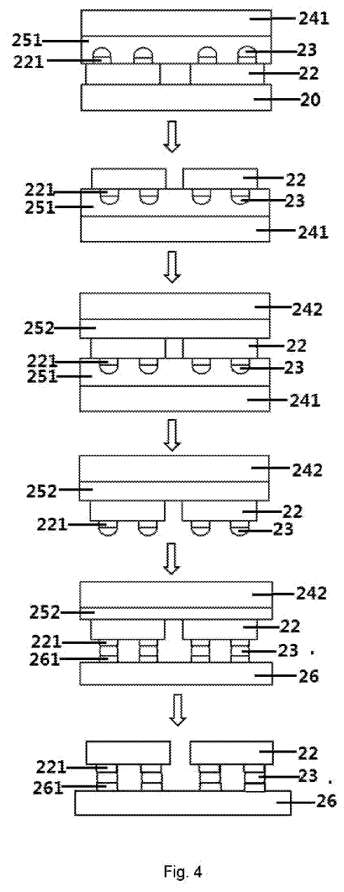

In a specific embodiment, an embodiment 2 of the application provides a die bonding method of an LED chip, and a process diagram is shown in FIG. 4. The transient substrate 24 may include a first transient substrate 241 and a second transient substrate 242. The operation S2 may include the following operations.

S21′, first release glue is coated or cladded on the first transient substrate, and second release glue is coated or cladded on the second transient substrate.

S22′, a surface of the LED chip fixed with the welding material and having the metal pad is oriented toward the first transient substrate, and the LED chip fixed with the welding material is fixed on the first transient substrate through the first release glue.

S23′, the growth substrate is removed by a laser lift-off technology, a surface of the LED chip fixed with the welding material and opposite to the first transient substrate is oriented toward the second transient substrate, and the LED chip fixed with the welding material is fixed on the second transient substrate through the second release glue.

During the specific implementation, preparation of the LED chip and a fixing process of the welding material in the embodiment 2 of the application are the same as preparation of the LED chip and a fixing process of the welding material in the embodiment 1. However, the difference is that there is no need to cut growth substrate 20 when the LED chip 22 fixed with the welding material 23 is obtained in the embodiment 2. When the LED chip 22 is subjected to the spot inspection, sorting and examination, the LED chip fixed with the welding material 23 is directly transferred onto the transient substrate 24. The transient substrate 24 in the embodiment may include the first transient substrate 241 and the second transient substrate 242. In the operation S2, the operation that the LED chip 22 fixed with the welding material 23 is transferred onto the transient substrate 24 is to transfer the LED chip 22 fixed with the welding material 23 onto the first transient substrate 241 and the second transient substrate 242. Before the operation that the LED chip 22 fixed with the welding material 23 is transferred onto the first transient substrate 241 and the second transient substrate 242, the first release glue 251 and the second release glue 252 further need to be coated or cladded on the first transient substrate 241 and the second transient substrate 242, respectively. In a specific embodiment, the first transient substrate 241 and the second transient substrate 242 may include, but not be limited to, the glass plate, the quartz glass, the sapphire and the silicon wafer. The first release glue 251 and the second release glue 252 may include, but not be limited to, the UV photolytic glue, the pyrolytic glue and the low-temperature dissolving glue.

During the specific implementation, when the welding material 23 is fixed onto the metal pad 221 of the LED chip 22 in the embodiment, the one surface of the LED chip 22 fixed with the welding material 23 and having the metal pad 221 is oriented toward the first transient substrate 241 coated or cladded with the first release glue 251 in advance, and then the one surface of the LED chip 22 having the metal pad 221 is fixed on the first transient substrate 241 through the first release glue 251.

During the specific implementation, because another surface of the LED chip 22 opposite to the metal pad 221 is fixed on the growth substrate 20, when the one surface of the LED chip having the metal pad 221 is fixed on the first transient substrate 241, the growth substrate 20 may be removed through the laser lift-off technology, to obtain the LED chip 22 fixed on the first transient substrate 241.

During the specific implementation, when the LED chip 22 fixed on the first transient substrate 241 is obtained in the embodiment, the one surface of the LED chip 22 fixed on the first transient substrate 241 and opposite to the first transient substrate 241 is further oriented toward the second transient substrate 242 coated or cladded with the second release glue 252 in advance, and then the one surface of the LED chip 22 opposite to the first transient substrate 241 is fixed on the second transient substrate 242 through the second release glue 252.

In a specific embodiment, release conditions of the first release glue are different from release conditions of the second release glue. After the operation S23′, the method may further include the following operation.

S24′, the first transient substrate is removed.

During the specific implementation, because the one surface of the LED chip 22 having metal pad 221 is fixed on the first transient substrate 241, in order to expose the welding material 23 on the metal pad so that the LED chip 22 is fixed on the receiving substrate 26 through the welding material 23 in a subsequent operation, the first transient substrate 241 needs to be further removed when the LED chip 22 is fixed on the second transient substrate 242 in the embodiment. Because the LED chip 22 is fixed with the first transient substrate 241 and the second transient substrate 242 through the first release glue 251 and the second release glue 252 respectively, after the LED chip 22 is fixed with the first transient substrate 241 and the second transient substrate 242 at the same time, the first transient substrate 241 may be removed by using the first release glue 251 and the second release glue 252 with different release conditions when the release conditions of the first release glue 251 are satisfied, without influencing the second transient substrate 242. For example, the first release glue 251 is the UV photolytic glue, the second release glue 252 is the pyrolytic glue. When the LED chip 22 is fixed on the first transient substrate 241 and the second transient substrate 242, the first transient substrate 241 is irradiated through the UV photolytic glue, in this way the first release glue 251 releases to remove the first transient substrate 241.

In a specific embodiment, after the operation S24′, the method may further include the following operations.

S25′, the metal pad of the LED chip fixed on the second transient substrate is aligned with the bonding pad of the receiving substrate, the welding material fixed on the LED chip is heated, and then the LED chip is fixed on the receiving substrate.

During the specific implementation, after the welding material 23 on the metal pad 221 is exposed upon removing the first transient substrate 241 when the release conditions of the first release glue 251 are satisfied, the metal pad 221 of the LED chip is further aligned with the bonding pad 261 of the receiving substrate 26, then the welding material 23 fixed on the LED chip 22 is heated, in this way the welding material 23 is melted down. Moreover, the LED chip 22 is fixed on the receiving substrate 26, wherein the mode of heating may include, but not be limited to, the reflow soldering, the vacuum baking and the laser heating.

In a specific embodiment, after the operation S25′, the method may further include the following operation.

S26′, the second transient substrate is removed.

During the specific implementation, after the LED chip 22 is fixed on the receiving substrate 26, the second transient substrate 242 is removed when the release conditions of the second release glue 252 are satisfied, that is, die bonding of the LED chip 22 is realized. The die bonding process may not be limited by the placement time after the welding material is printed, and the manufacturing process is stable.

In a specific embodiment, the embodiment further provides a display device. The display device may include a display substrate fixed with an LED chip. The LED chip is fixed on the display substrate with the die bonding method of the LED chip. The die bonding method of the LED chip is suitable for manufacturing of an integrated large-size LED display device because it is not limited by placement time when a welding material is printed.

To sum up, the application provides the die bonding method of the LED chip and the display device. The method may include: the welding material is fixed on the metal pad of the LED chip, the LED chip fixed with the welding material is transferred onto the transient substrate, the metal pad of the LED chip on the transient substrate is aligned with the bonding pad on the receiving substrate, the welding material fixed on the LED chip is heated, and then the LED chip is fixed on the receiving substrate. The welding material is printed and fixed on the metal pad of the LED chip first in the application, then the metal pad of the LED chip is aligned with the bonding pad on the receiving substrate, and the welding material is heated, in this way the LED chip is fixed on the receiving substrate, the whole die bonding process may not be limited by the placement time after the welding material is printed, the manufacturing process is stable, and the method is suitable for the manufacturing of the integrated large-size LED display device.

It is to be understood that system applications of the application are not limited by the abovementioned examples. Any improvements or variations may be made by those of ordinary skill in the art, and these improvements or variations shall fall within the scope of protection as defined by the appended claims of the application.

What is claimed is:

1. A die bonding method of an LED chip, comprising:
fixing a welding material on a metal pad of the LED chip;
transferring the LED chip fixed with the welding material onto a transient substrate;
aligning the metal pad of the LED chip on the transient substrate with a bonding pad on a receiving substrate, heating the welding material fixed on the LED chip to fix the LED chip on the receiving substrate.

2. The die bonding method of the LED chip according to claim 1, wherein fixing the welding material on the metal pad of the LED chip comprises:
printing the welding material on the metal pad of the LED chip, to obtain an LED chip printed with the welding material; and
performing reflow soldering for the LED chip printed with the welding material, to fix the welding material on the metal pad of the LED chip.

3. The die bonding method of the LED chip according to claim 2, wherein after fixing the welding material on the metal pad of the LED chip, the method further comprises:
performing spot inspection, sorting and examination for the LED chip, and transferring the LED chip having a wavelength difference within a range defined based on one or more preset thresholds onto one blue film.

4. The die bonding method of the LED chip according to claim 3, wherein transferring the LED chip fixed with the welding material onto the transient substrate comprises:
coating or cladding release glue on the transient substrate;
orienting the metal pad of the LED chip on the blue film toward a direction away from the transient substrate, and transferring the LED chip fixed with the welding material onto the transient substrate through the release glue.

5. The die bonding method of the LED chip according to claim 4, wherein after aligning the metal pad of the LED chip on the transient substrate with the bonding pad on the receiving substrate, heating the welding material fixed on the LED chip, and fixing the LED chip on the receiving substrate, the method further comprises:
removing the transient substrate.

6. The die bonding method of the LED chip according to claim 2, wherein the transient substrate comprises a first transient substrate and a second transient substrate;
transferring the LED chip fixed with the welding material onto the transient substrate comprises:
coating or cladding first release glue on the first transient substrate; coating or cladding second release glue on the second transient substrate;
orienting a surface of the LED chip fixed with the welding material and having the metal pad toward the first transient substrate, and fixing the LED chip fixed with the welding material on the first transient substrate through the first release glue; and
removing a growth substrate through a laser lift-off technology, orienting a surface of the LED chip fixed with the welding material and opposite to the first transient substrate toward the second transient substrate, and fixing the LED chip fixed with the welding material on the second transient substrate through the second release glue.

7. The die bonding method of the LED chip according to claim 6, wherein release conditions of the first release glue are different from release conditions of the second release glue; and
after fixing the LED chip fixed with the welding material on the second transient substrate through the second release glue, the method further comprises:
removing the first transient substrate.

8. The die bonding method of the LED chip according to claim 7, wherein after removing the first transient substrate, the method further comprises:
aligning the metal pad of the LED chip fixed on the second transient substrate with the bonding pad on the receiving substrate, heating the welding material fixed on the LED chip, and fixing the LED chip on the receiving substrate, wherein a mode of heating the welding material fixed on the LED chip comprises one of reflow soldering, vacuum baking or laser heating.

9. The die bonding method of the LED chip according to claim 8, wherein after aligning the metal pad of the LED chip fixed on the second transient substrate with the bonding pad on the receiving substrate, heating the welding material fixed on the LED chip, and fixing the LED chip on the receiving substrate, the method further comprises:
removing the second transient substrate.

10. A display device, comprising a display substrate fixed with an LED chip; and the LED chip is fixed on the display substrate with a die bonding method of the LED chip, wherein the die bonding method of the LED chip comprises:
fixing a welding material on a metal pad of the LED chip;
transferring the LED chip fixed with the welding material onto a transient substrate;
aligning the metal pad of the LED chip on the transient substrate with a bonding pad on a receiving substrate, heating the welding material fixed on the LED chip to fix the LED chip on the receiving substrate.

11. The display device according to claim 10, wherein fixing the welding material on the metal pad of the LED chip comprises:
printing the welding material on the metal pad of the LED chip, to obtain an LED chip printed with the welding material; and
performing reflow soldering for the LED chip printed with the welding material, to fix the welding material on the metal pad of the LED chip.

12. The display device according to claim 11, wherein after fixing the welding material on the metal pad of the LED chip, the method further comprises:
performing spot inspection, sorting and examination for the LED chip, and transferring the LED chip having a wavelength difference within a range defined based on one or more preset thresholds onto one blue film.

13. The display device according to claim 12, wherein transferring the LED chip fixed with the welding material onto the transient substrate comprises:
coating or cladding release glue on the transient substrate;
orienting the metal pad of the LED chip on the blue film toward a direction away from the transient substrate, and transferring the LED chip fixed with the welding material onto the transient substrate through the release glue.

14. The display device according to claim 13, wherein after aligning the metal pad of the LED chip on the transient substrate with the bonding pad on the receiving substrate, heating the welding material fixed on the LED chip, and fixing the LED chip on the receiving substrate, the method further comprises:
removing the transient substrate.

15. The display device according to claim 11, wherein the transient substrate comprises a first transient substrate and a second transient substrate;
transferring the LED chip fixed with the welding material onto the transient substrate comprises:
coating or cladding first release glue on the first transient substrate; coating or cladding second release glue on the second transient substrate;
orienting a surface of the LED chip fixed with the welding material and having the metal pad toward the first transient substrate, and fixing the LED chip fixed with the welding material on the first transient substrate through the first release glue; and
removing a growth substrate through a laser lift-off technology, orienting a surface of the LED chip fixed with the welding material and opposite to the first transient substrate toward the second transient substrate, and fixing the LED chip fixed with the welding material on the second transient substrate through the second release glue.

16. The display device according to claim 15, wherein release conditions of the first release glue are different from release conditions of the second release glue; and
after fixing the LED chip fixed with the welding material on the second transient substrate through the second release glue, the method further comprises:
removing the first transient substrate.

17. The display device according to claim 16, wherein after removing the first transient substrate, the method further comprises:
aligning the metal pad of the LED chip fixed on the second transient substrate with the bonding pad on the receiving substrate, heating the welding material fixed on the LED chip, and fixing the LED chip on the receiving substrate, wherein a mode of heating the welding material fixed on the LED chip comprises one of reflow soldering, vacuum baking or laser heating.

18. The display device according to claim 17, wherein after aligning the metal pad of the LED chip fixed on the second transient substrate with the bonding pad on the receiving substrate, heating the welding material fixed on the LED chip, and fixing the LED chip on the receiving substrate, the method further comprises:
removing the second transient substrate.
